(19) United States
(12) Patent Application Publication
(10) Pub. No.: US 2013/0107142 A1
(43) Pub. Date: May 2, 2013

(54) TELEVISION AND ELECTRONIC APPARATUS

(71) Applicant: Hideo Shirasaka, Hamura-shi (JP)

(72) Inventor: Hideo Shirasaka, Hamura-shi (JP)

(73) Assignee: KABUSHIKI KAISHA TOSHIBA, Tokyo (JP)

(21) Appl. No.: 13/605,597

(22) Filed: Sep. 6, 2012

(30) Foreign Application Priority Data
Oct. 31, 2011 (JP) 2011-239115

(51) Int. Cl. H05K 7/02; H04N 5/64

(52) U.S. Cl. 348/843; 361/679.01; 348/E05.128

(57) ABSTRACT

According to at least one embodiment, an electronic apparatus includes a housing and a flexible display in the housing. A central portion of the display is free from the housing. At least two ends of the display are attached to the housing. In certain configurations, the electronic apparatus is a television.

### CROSS-REFERENCE TO RELATED APPLICATIONS

This application is based upon and claims the benefit of priority from prior Japanese Patent Application No. 2011-239115, filed Oct. 31, 2011, the entire contents of which are incorporated herein by reference.

### FIELD

Embodiments described herein relate generally to electronic apparatuses including televisions.

### BACKGROUND

Some electronic apparatuses include display devices.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view of a television according to a first embodiment;

FIG. 2 is an exemplary cross-sectional view of the television illustrated in FIG. 1;

FIG. 3 is an exemplary perspective view of an electronic apparatus according to a second embodiment;

FIG. 4 is an exemplary plan view of the internal structure of a display unit illustrated in FIG. 3;

FIG. 5 is an exemplary perspective view of a portion of a display device illustrated in FIG. 4;

FIG. 6 is an exemplary perspective view of a process of attaching the display device illustrated in FIG. 4;

FIG. 7 is an exemplary cross-sectional view of a portion of the display unit illustrated in FIG. 4;

FIG. 8 is an exemplary cross-sectional view of a portion of the display unit illustrated in FIG. 4;

FIG. 9 is an exemplary cross-sectional view of a portion of the display unit illustrated in FIG. 4;

FIG. 10 is an exemplary cross-sectional view of a portion of a display unit according to a first modification of the second embodiment;

FIG. 11 is an exemplary cross-sectional view of a portion of a display unit according to a second modification of the second embodiment;

FIG. 12 is an exemplary cross-sectional view of a portion of a display unit according to a third modification of the second embodiment;

FIG. 13 is an exemplary perspective view of a portion of a display unit according to a third embodiment;

FIG. 14 is an exemplary perspective view of a holder illustrated in FIG. 13;

FIG. 15 is an exemplary perspective view of a supporting body illustrated in FIG. 13;

FIG. 16 is an exemplary perspective view of an attachment portion illustrated in FIG. 13;

FIG. 17 is an exemplary cross-sectional view of an attachment structure illustrated in FIG. 13;

FIG. 18 is an exemplary cross-sectional view of the attachment structure illustrated in FIG. 13;

FIG. 19 is an exemplary cross-sectional view of the attachment structure illustrated in FIG. 13;

FIG. 20 is an exemplary perspective view of a portion of the attachment structure illustrated in FIG. 13;

FIG. 21 is an exemplary perspective view of a portion of the attachment structure illustrated in FIG. 13;

FIG. 22 is an exemplary cross-sectional view of the attachment structure illustrated in FIG. 13;

FIG. 23 is an exemplary cross-sectional view of an attachment structure according to a modification of the third embodiment;

FIG. 24 is an exemplary plan view of the attachment structure illustrated in FIG. 13;

FIG. 25 is an exemplary perspective view of a holder according to another modification of the third embodiment;

FIG. 26 is an exemplary plan view of the internal structure of a display unit according to a fourth embodiment;

FIG. 27 is an exemplary plan view of the internal structure of a display unit according to a fifth embodiment;

FIG. 28 is an exemplary plan view of the internal structure of a display unit according to a sixth embodiment;

FIG. 29 is an exemplary cross-sectional view of a portion of a display unit according to a seventh embodiment;

FIG. 30 is an exemplary plan view of the positional relation between a second boss and a second opening illustrated in FIG. 29;

FIG. 31 is an exemplary cross-sectional view of a portion of a display unit according to an eighth embodiment;

FIG. 32 is an exemplary exploded perspective view of a display unit according to a ninth embodiment;

FIG. 33 is an exemplary perspective view of an electronic apparatus according to a tenth embodiment;

FIG. 34 is an exemplary perspective view of the electronic apparatus illustrated in FIG. 33; and

FIG. 35 is an exemplary cross-sectional view of the electronic apparatus illustrated in FIG. 33.

### DETAILED DESCRIPTION

Various embodiments will be described hereinafter with reference to the accompanying drawings.

In general, according to one embodiment, an electronic apparatus comprises a housing and a flexible display in the housing. A central portion of the display is free from the housing. At least two ends of the display are attached to the housing.

Hereinafter, embodiments will be described with reference to the drawings.

### First Embodiment

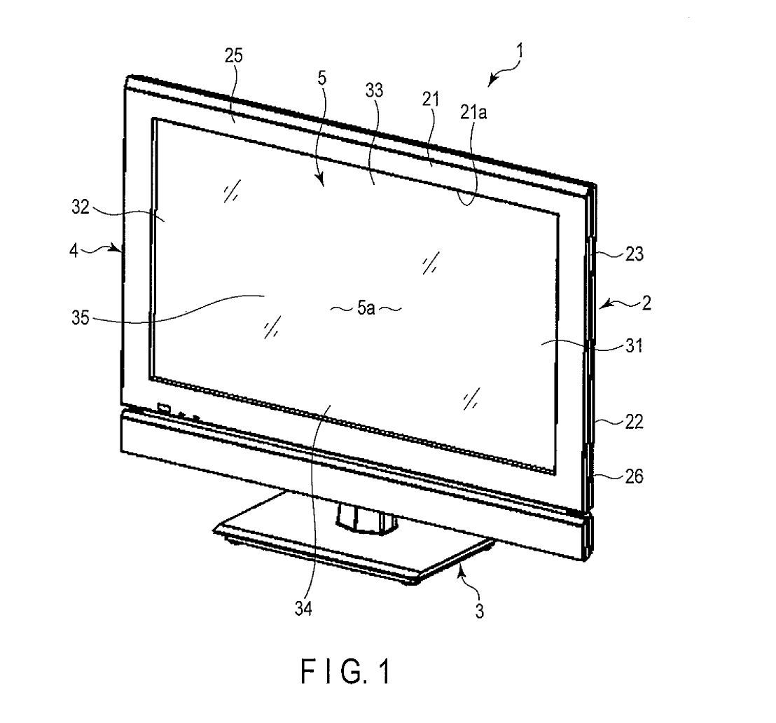

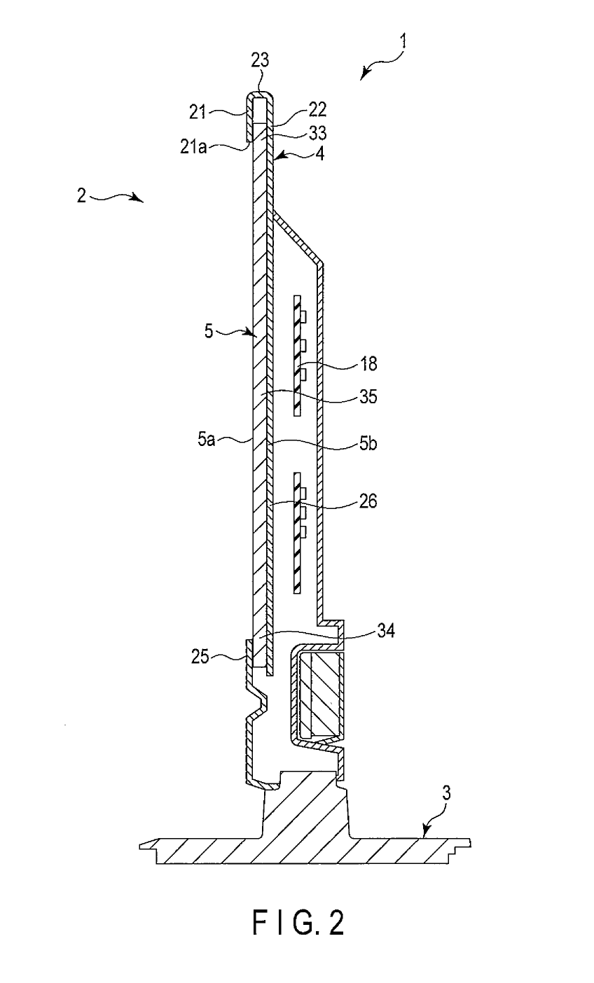

FIGS. 1 and 2 illustrate a television 1 according to a first embodiment. The television 1 is an example of an “electronic apparatus”. As illustrated in FIG. 1, the television 1 includes a display unit 2 and a stand 3 supporting the display unit 2.

As illustrated in FIGS. 1 and 2, the display unit 2 includes a housing 4 and a display device 5 (i.e., display) accommodated in the housing 4. The display device 5 is flexible and is fixed to the housing 4. The stand 3 is an example of a “supporting portion (i.e., supporter)” supporting the display unit 2 (i.e., housing 4).

The components have substantially the same detailed structures as those in a second embodiment. The second embodiment will be described in detail. Therefore, components having the same or similar functions to the second embodiment are denoted by the same reference numerals and the description thereof will not be repeated.

### Second Embodiment

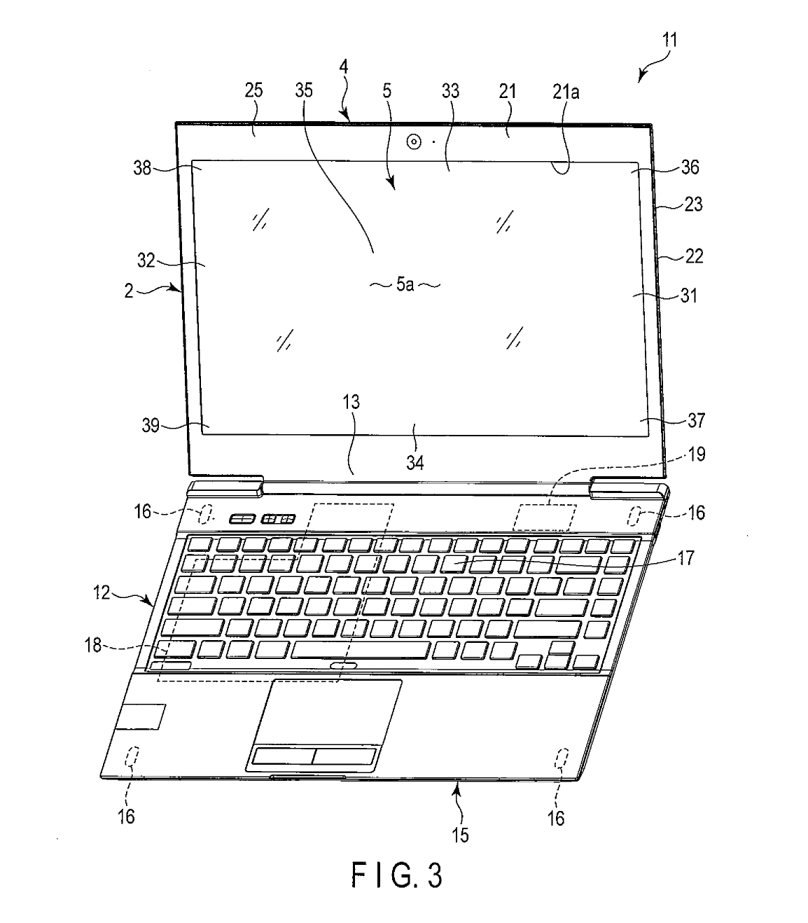

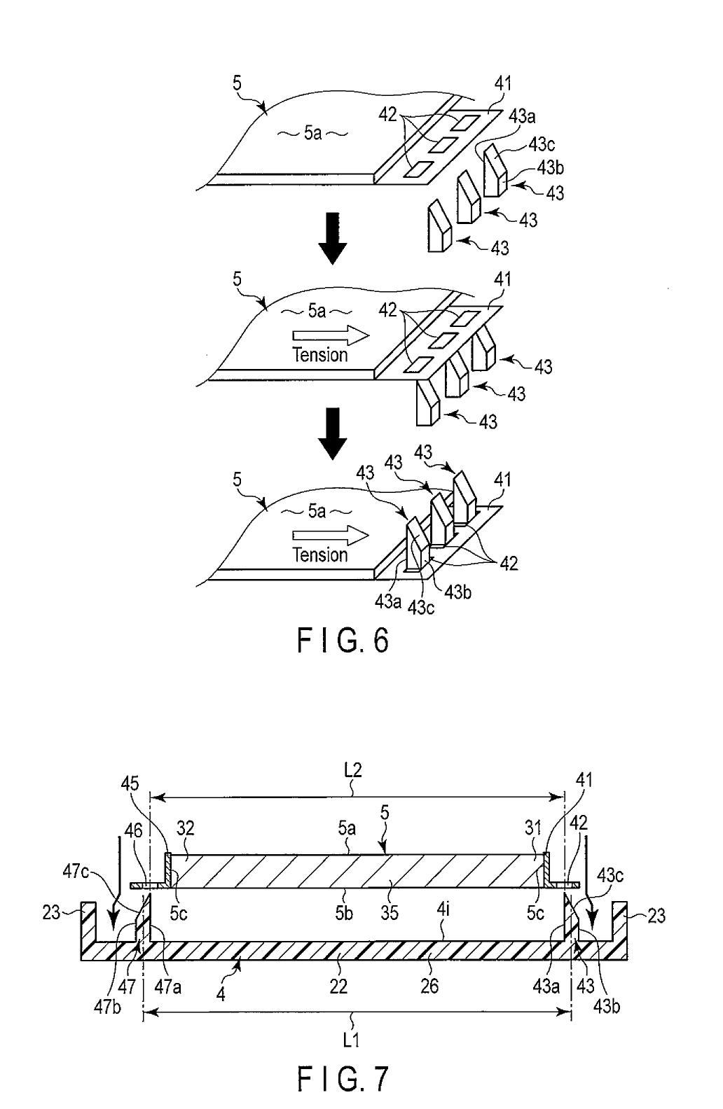

Next, an electronic apparatus 11 according to a second embodiment will be described with reference to FIGS. 3 to 9. The electronic apparatus 11 according to this embodiment is, for example, a notebook portable computer (i.e., notebook PC). The electronic apparatus 11 includes a first unit 12, a second unit 2, and a hinge portion 13.

The first unit 12 is a main unit. The first unit 12 includes a first housing 15. The first housing 15 faces the upper surface of a desk (i.e., mounting surface, e.g., outer mounting surface) when the electronic apparatus 11 is placed on the desk. The first housing 15 is provided with a plurality of legs 16 (i.e., supporting portions) which come into contact with the upper surface of the desk and support the electronic apparatus 11.

The first housing 15 is provided with an input unit 17. An example of the input unit 17 is a keyboard. The “input unit” may be a touch panel (e.g., touch sensor) or other input devices. A circuit board 18, which is a main board, and a module 19 are accommodated in the first housing 15. An example of the module 19 is a memory device. The “module” may be a cooling device, an ODD unit, or other electronic components.

The first unit 12 (i.e., first housing 15) is an example of a supporting portion which supports the second unit 2 (i.e., second housing 4). When the electronic apparatus 11, such as a slate PC (e.g., tablet PC), includes one housing 4, the legs 16 (e.g., rubber legs) provided on the housing 4 are an example of the supporting portion (i.e., supporter).

As illustrated in FIG. 3, the second unit 2 is a display unit. The second unit 2 is rotatably (i.e., openably) connected to the rear end of the first unit 12 by the hinge portion 13. In this way, the electronic apparatus 11 can be rotated between a first state in which the first unit 12 and the second unit 2 overlap each other and a second state in which the first unit 12 and the second unit 2 are opened.

The second unit 2 includes a second housing 4 (hereinafter, referred to as a housing 4) and a display device 5 (i.e., a display portion, a display device, a display module, a display unit, or a display) accommodated in the housing 4. The display device 5 according to this embodiment is a flexible display (i.e., a sheet display, a plastic display, a deformable display, or a thin display) having flexibility.

The display device 5 includes a display surface 5a (i.e., a display screen or a first surface) and a rear surface 5b (i.e., a back surface or a second surface) opposite to the display surface 5a. For example, an image is displayed on the display surface 5a under the control of a CPU which is provided on a circuit board 18. Herein, the “image” is defined to include various kinds of information displayed on the screen, such as characters, symbols, figures, sentences, images, moving pictures, and Web pages, but is not limited to, for example, illustrations or pictures. The display device 5 will be described in detail below.

As illustrated in FIG. 3, the housing 4 includes a front wall 21 (i.e., first wall), a rear wall 22 (i.e., a back wall or a second wall), and a circumferential wall 23 (i.e., third wall) and has a flat box shape. The front wall 21 extends substantially in parallel to the display surface 5a. An opening 21a through which the display surface 5a is exposed is provided in the front wall 21.

Herein, the term “exposure” includes a case in which the display surface is directly exposed through the opening and a case in which a transparent member (or an opaque member), such as a touch sensor, is provided between the opening and the display surface and the display surface is exposed to the outside through the transparent member (or the opaque member). That is, any case may correspond to the “exposure” herein as long as the display surface can be seen from the outside.

The rear wall 22 is opposite to the front wall 21 with the display device 5 interposed therebetween. A space is provided between the rear wall 22 and the front wall 21 and the rear wall 22 extends substantially in parallel to the front wall 21. The circumferential wall 23 extends in a direction crossing (e.g., substantially perpendicular to) the front wall 21 and the rear wall 22 and connects the edge of the front wall 21 and the edge of the rear wall 22.

The housing 4 includes a mask 25 (i.e., a mask portion or a first member) and a cover 26 (i.e., a cover portion or a second member). The mask 25 includes the front wall 21. The cover 26 is opposite to the mask 25 with the display device 5 interposed therebetween and includes the rear wall 22 and the circumferential wall 23. The mask 25 and the cover 26 are combined with each other to form the housing 4. In this embodiment, the cover 26 is made of plastic. The cover 26 (i.e., rear wall 22) covers the rear surface 5b of the display device 5.

Next, the display device 5 and the mounting structure thereof will be described in detail.

The display device 5 according to this embodiment has a light weight, is thin like a paper, and is bendable or rollable. The display device 5 includes a flexible panel and a flexible backlight.

The flexible panel includes a first polarizing plate, a first plastic substrate, a liquid crystal layer, a second plastic substrate, and a second polarizing plate. The liquid crystal layer is interposed between the first and second plastic substrates. The first plastic substrate (e.g., first film substrate) is a color filter substrate. The second plastic substrate (e.g., second film substrate) is an array substrate. The flexible backlight includes a diffusion plate, a light guide plate, and an LED (i.e., light-emitting diode, or light source). The display device 5 is not limited to a liquid crystal display, but may be an organic EL display or other types of displays.

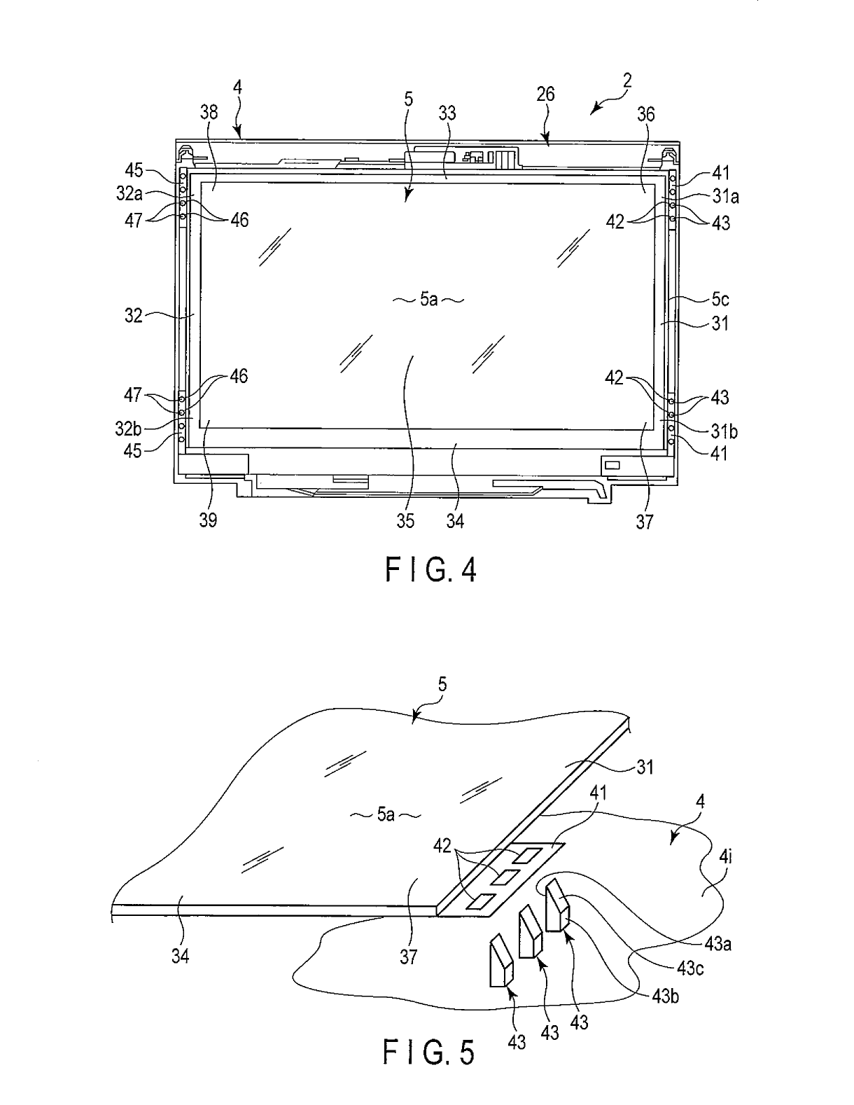

As illustrated in FIG. 4, the display device 5 has a rectangular shape. The display device 5 includes a first end 31, a second end 32, a third end 33, and a fourth end 34. The first end 31 extends in the lateral direction of the display device 5. The second end 32 is opposite to the first end 31 and extends substantially in parallel to the first end 31. The display surface 5a is disposed between the first end 31 and the second end 32.

The third end 33 extends in a direction crossing (e.g., substantially perpendicular to) the first end 31 and the second end 32. The third end 33 extends in the longitudinal direction of the display device 5. The fourth end 34 is opposite to the third end 33 and extends substantially in parallel to the third end 33. The display surface 5a is disposed between the third end 33 and the fourth end 34.

The display device 5 includes a central portion 35 and four corners 36, 37, 38, and 39. The first corner 36 is defined by the first end 31 and the third end 33. The second corner 37 is defined by the first end 31 and the fourth end 34. The third corner 38 is defined by the second end 32 and the third end 33. The fourth corner 39 is defined by the second end 32 and the fourth end 34.

The first end 31 includes a first portion 31a which is disposed at (or adjacent to) the first corner 36 and a second portion 31b which is opposite to the first portion 31a and is disposed at (or adjacent to) the second corner 37. The second end 32 includes a first portion 32a which is disposed at (or adjacent to) the third corner 38 and a second portion 32b which is opposite to the first portion 32a and is disposed at (or adjacent to) the fourth corner 39.

As illustrated in FIG. 4, a plurality of (e.g., two) first attachment portions 41 (i.e., first attachment, or first fixing portions) are provided at the first end 31. The two first attachment portions 41 are separately provided on both sides of the first end 31. That is, one of the first attachment portions 41 is disposed in the first portion 31a (i.e., first corner 36) of the first end 31. The other first attachment portion 41 is disposed in the second portion 31b (i.e., second corner 37) of the first end 31. The first attachment portion 41 is made of, for example, metal (e.g., sheet metal). The first attachment portion 41 may be made of plastic.

For example, a plurality of first openings 42 (i.e., first engaging portions, first fitting portions, first fixing portions, or first holders) are provided in the first attachment portion 41. The plurality of first openings 42 are arranged along the first end 31. The first opening 42 is, for example, a rectangular hole. The first opening 42 may be a circular hole. Herein, each of the first engaging portion, the first fitting portion, the first fixing portion, and the first holder is not limited to a through hole, but may be a concave portion, a protruding portion, a projection portion, a claw portion, a portion (e.g., a region or an end) between the cover 26 and the mask 25, a portion (e.g., a region or an end) covered with the housing 4 (e.g., mask 25), or portions with other shapes.

In this embodiment, the display device 5 is attached to the cover 26. As illustrated in FIGS. 5 to 8, the cover 26 includes a plurality of first projections 43 (i.e., first supporters, first protruding portions, or first supporting portions) protruding from the inner surface thereof. Each of the first projections 43 is provided at a position corresponding to the first opening 42. The plurality of first projections 43 are inserted into the plurality of first openings 42. The first projection 43 has a rectangular cross section corresponding to the shape of the first opening 42. The first projection 43 may have a cylindrical shape.

Similarly, as illustrated in FIG. 4, a plurality of (e.g., two) second attachment portions 45 (i.e., second attachment, or second fixing portions) are provided at the second end 32. The two second attachment portions 45 are separately provided on both sides of the second end 32. That is, one of the second attachment portions 45 is disposed in the first portion 32a (i.e., third corner 38) of the second end 32. The other second attachment portion 45 is disposed in the second portion 32b (i.e., fourth corner 39) of the second end 32. The second attachment portion 45 is made of, for example, metal (e.g., sheet metal). The second attachment portion 45 may be made of plastic.

The first attachment portion 41 and the second attachment portion 45 may be formed separately from the display device 5 and may be fixed to the display device 5. The first attachment portion 41 and the second attachment portion 45 may be a portion of the structure which holds at least one of the flexible panel and the flexible backlight. The first attachment portion 41 and the second attachment portion 45 may be provided integrally with the display device 5 and may be a portion of the display device 5.

For example, a plurality of second openings 46 (i.e., second engaging portions, second fitting portions, second fixing portions, or second holders) are provided in the second attachment portion 45. The plurality of second openings 46 are arranged along the second end 32. The second opening 46 is, for example, a rectangular hole. The second opening 46 may be a circular hole. Herein, each of the second engaging portion, the second fitting portion, the second fixing portion, and the second holder is not limited to a through hole, but may be a concave portion, a protruding portion, a projection portion, a claw portion, a portion (e.g., a region or an end) between the cover 26 and the mask 25, a portion (e.g., a region or an end) covered with the housing 4 (e.g., mask 25), or portions with other shapes.

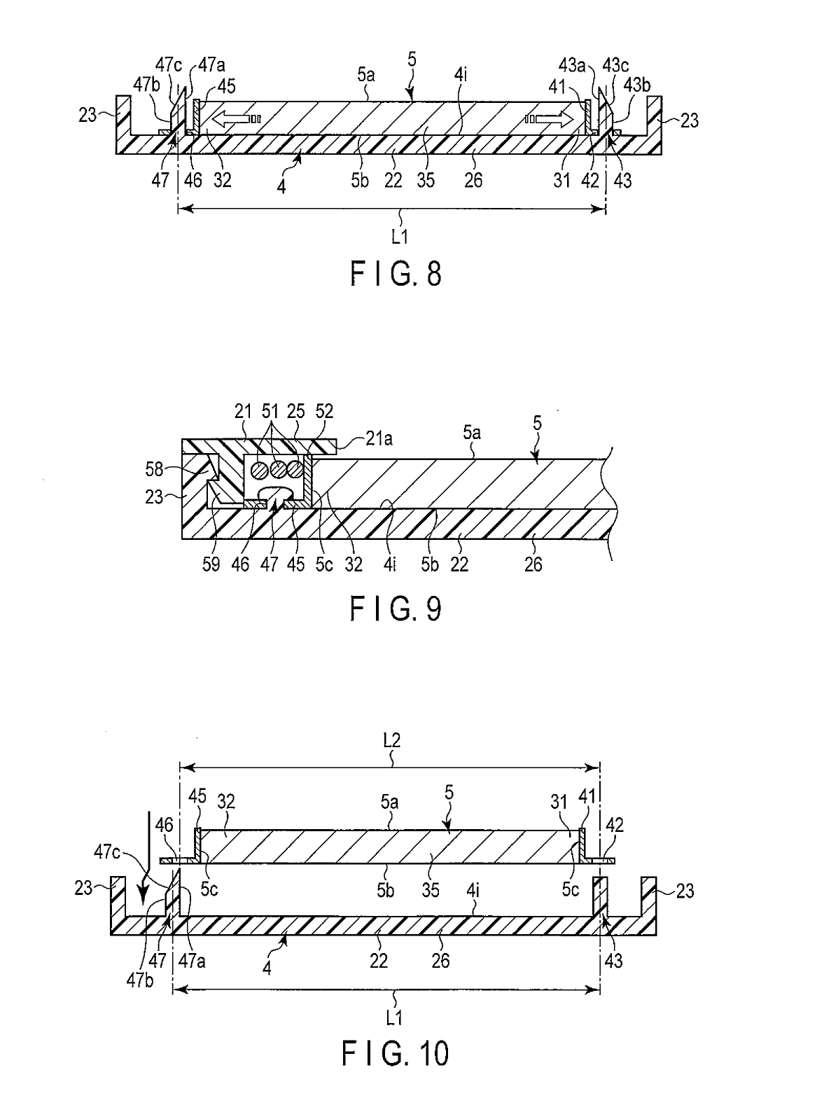

As illustrated in FIGS. 7 and 8, the cover 26 includes a plurality of second projections 47 (i.e., second supporters, second protruding portions, or second supporting portions) protruding from the inner surface thereof. Each of the second projections 47 is provided at a position corresponding to the second opening 46. The plurality of second projections 47 are inserted into the plurality of second openings 46. The second projection 47 has a rectangular cross section corresponding to the shape of the second opening 46. The second projection 47 may be a cylindrical shape.

Next, the shape and operation of the first projection 43 and the second projection 47 will be described.

As illustrated in FIG. 4, the plurality of first projections 43 and the plurality of second projections 47 are provided at the corresponding positions such that they form pairs. That is, the plurality of first projections 43 and the second projections 47 whose number is the same as that of first projections 43 are separately provided on both sides of the display device 5 in the longitudinal direction of the display device 5.

As illustrated in FIG. 7, the first projection 43 includes a first side 43a (i.e., first side surface, or first surface) facing the second projection 47 and a second side 43b (i.e., second side surface, or second surface) opposite to the first side 43a. The second side 43b includes an inclined surface 43c (i.e., inclined portion) which is provided at least at the leading end of the first projection 43. The inclined surface 43c is inclined in the direction in which the surface 43c is away from the second projection 47 while advancing from the leading end toward the base end of the first projection 43. Herein, the “base end of the projection” indicates a portion of the projection connected to the inner surface of the housing 4. The “leading end of the projection” indicates the end of the projection which protrudes toward the inside of the housing.

Similarly, the second projection 47 includes a first side 47a (i.e., first side surface, or first surface) facing the first projection 43 and a second side 47b (i.e., second side surface, or second surface) opposite to the first side 47a. The second side 47b includes an inclined surface 47c (i.e., inclined portion) which is provided at least at the leading end of the second projection 47. The inclined surface 47c is inclined in the direction in which the surface 47c is away from the first projection 43 while advancing from the leading end toward the base end of the second projection 47.

As illustrated in FIG. 7, a distance L1 (i.e., first distance, or first interval) between the first projection 43 and the second projection 47 is greater than a distance L2 (i.e., second distance, or second interval) between the first opening 42 and the second opening 46. The distance L1 between the first projection 43 and the second projection 47 is the distance between the center line of the first projection 43 and the center line of the second projection 47. Similarly, the distance L2 between the first opening 42 and the second opening 46 is the distance between the center line of the first opening 42 and the center line of the second opening 46.

In this embodiment, the first opening 42 (e.g., the edge of the first opening 42) is guided by the inclined surface 43c of the first projection 43 and is fitted to the first projection 43 while moving in the direction in which it is away from the second projection 47. Similarly, the second opening 46 (e.g., the edge of the second opening 46) is guided by the inclined surface 47c of the second projection 47 and is fitted to the second projection 47 while moving in the direction in which it is away from the first projection 43.

In this way, the distance between the first opening 42 and the second opening 46 after the display device is attached to the cover 26 is greater than the distance between the first opening 42 and the second opening 46 before the display device is attached to the cover 26. Therefore, with the display device attached to the cover 26, tensile stress (e.g., pretension) is applied between the first end 31 and the second end 32 such that the display device 5 is stretched in the longitudinal direction. In this way, the display surface 5a is stretched in the longitudinal direction and the flatness of the display surface 5a is improved.

No fixing portion is provided in the central portion 35 of the display device 5. The central portion 35 of the display device 5 is not fixed to the cover 26, but is free with respect to the housing 4. A region (i.e., portion) of the rear surface 5b of the display device 5 between the first opening 42 and the second opening 46 can be displaced (i.e., movable) relative to the cover 26 (e.g., rear wall 22).

Two or more ends of the display device 5 are fixed to the housing 4. For example, the four corners 36, 37, 38, and 39 of the display device 5 are fixed to the housing 4.

As illustrated in FIG. 5, in this embodiment, the first opening 42 has a rectangular shape. The first projection 43 has a rectangular cross section (i.e., a transverse section or a cross section along the inner surface of the housing) corresponding to the shape of the first opening 42. Therefore, the first projection 43 is inserted into the first opening 42 to regulate the rotation of the display device 5 on the first projection 43.

Similarly, the second opening 46 has a rectangular shape. The second projection 47 has a rectangular cross section (i.e., a transverse section or a cross section along the inner surface of the housing) corresponding to the shape of the second opening 46. Therefore, the second projection 47 is inserted into the second opening 46 to regulate the rotation of the display device 5 on the second projection 47.

The leading end of the first projection 43 is welded (i.e., fixed) to the first attachment portion 41 with the first projection 43 inserted into the first opening 42. That is, heat and load are applied to the leading end of the first projection 43 to crush the leading end. In this way, the first attachment portion 41 is fixed to the first projection 43.

As illustrated in FIG. 9, similarly to the first projection 43, the leading end of the second projection 47 is welded (e.g., fixed) to the second attachment portion 45 with the second projection 47 inserted into the second opening 46. That is, heat and load are applied to the leading end of the second projection 47 to crush the leading end. In this way, the second attachment portion 45 is fixed to the second projection 47.

As illustrated in FIG. 9, a plurality of cables 51 are accommodated in the housing 4. The cable 51 is, for example, an antenna cable or a cable connected to the display device 5. The cable 51 is not limited thereto, but various kinds of cables accommodated in the housing 4 may be used.

The plurality of cables 51 pass through a space between the leading end (e.g., welding portion) of the second projection 47 and the mask 25 (e.g., front wall 21). The plurality of cables 51 may pass through a space between the leading end (e.g., welding portion) of the first projection 43 and the mask 25 (e.g., front wall 21).

As illustrated in FIG. 9, the second attachment portion 45 includes a portion 52 (e.g., a protruding portion, a supporting portion, or a receiving portion) which protrudes toward the mask 25 farther than the display surface 5a. Similarly, the first attachment portion 41 includes a portion 52 (e.g., a protruding portion, a supporting portion, or a receiving portion) which protrudes toward the mask 25 farther than the display surface 5a. The first attachment portion 41 and the second attachment portion 45 may be provided in the thickness range of the display device 5 such that it does not include the protruding portion 52.

According to this structure, it is possible to reduce the thickness of the electronic apparatus 11. That is, in this embodiment, the electronic apparatus 11 includes the housing 4 and the flexible display device 5 which is accommodated in the housing 4. The flexible display device is thinner than, for example, a general LCD unit. Therefore, since a flexible display device is used, it is possible to reduce the thickness of an electronic apparatus.

The inventors studied and found that it was difficult to maintain the flatness of the display surface of a flexible display device. That is, when the flexible display device is attached to the housing by the same method as that used to attach the general LCD unit, the display surface is likely to be curved due to the weight of the display device. The curved display surface has an effect on the functionality (e.g., the accuracy of the screen) of image display.

In this embodiment, the central portion 35 of the display device 5 is not fixed to the housing 4, but two ends 31 and 32 thereof are fixed to the housing 4. According to this structure, the central portion 35 of the display device 5 is likely to be stretched, which makes it possible to improve the flatness of the display surface 5a.

In this embodiment, the display device 5 includes the first end 31 having the first openings 42 and the second end 32 having the second openings 46. The housing 4 includes the first projections 43 inserted into the first openings 42 and the second projections 47 inserted into the second openings 46. The distance L1 between the first projection 43 and the second projection 47 is greater than the distance L2 between the first opening 42 and the second opening 46.

According to this structure, tensile stress is applied between the first end 31 and the second end 32 with the display device 5 attached to the housing 4. Therefore, the display device 5 is stretched in the longitudinal direction (i.e., a direction substantially in parallel to the display surface 5a). In this way, the display surface 5a is less likely to be curved and it is possible to improve the flatness of the display surface 5a.

In this embodiment, the second projection 47 includes the first side surface 47a facing the first projection 43 and the second side surface 47b opposite to the first side surface 47a. The second side surface 47b includes the inclined surface 47c which is inclined in the direction in which the surface 47c is away from the first projection 43 while advancing from the leading end toward the base end of the second projection 47. In this way, even in the structure in which the distance L1 between the first projection 43 and the second projection 47 is greater than the distance L2 between the first opening 42 and the second opening 46, it is possible to attach the first opening 42 and the second opening 46 to the first projection 43 and the second projection 47 with a relatively simply structure.

In this embodiment, in the display device 5, the second opening 46 is guided by the inclined surface 47c and is engaged with the second projection 47. In this way, it is possible to smoothly fit the second opening 46 to the second projection 47. This operation holds for the first opening 42 and the first projection 43.

In this embodiment, the second opening 46 has a rectangular shape. The second projection 47 has a rectangular cross section corresponding to the shape of the second opening 46. In this way, the second projection 47 is inserted into the second opening 46 to regulate the rotation of the display device 5 on the second projection 47. According to this structure, it is possible to stably fix the display device 5 and further improve the flatness of the display surface 5a. This operation holds for the first opening 42 and the first projection 43.

In this embodiment, the display device 5 is welded to the housing 4. The fixing portion by welding is lower than a fixing portion by, for example, a boss and a screw. Therefore, it is possible to further reduce the thickness of the electronic apparatus 11. This operation holds for the first opening 42 and the first projection 43. The first attachment portion 41 and the second attachment portion 45 have a function of maintaining the shape of the display device 5 in addition to a welding function.

For example, an LCD unit including glass liquid crystal is relatively heavy. Therefore, in order to fix the LCD unit, it is necessary to relatively firmly fix the LCD unit to the housing with, for example, screws.

In contrast, the flexible display device 5 according to this embodiment is relatively light. Therefore, the display device 5 can be supported by a fixing method using welding, without using fixing unit, such as screws. That is, it is possible to mount the display device 5 with a light weight. In addition, a supporting structure, such as a rib for supporting the LCD unit, may not be used. Therefore, it is possible to reduce the size of the electronic apparatus 11.

In this embodiment, the cable 51 passes through the space between the leading end of the second projection 47 and the mask 25. According to this structure, the fixing portion fixing the display device 5 and the cable 51 can be arranged so as to overlap each other in the thickness direction of the housing 4. Therefore, it is possible to reduce the area (i.e., size) required for the housing 4 and thus reduce the size of the electronic apparatus 11. The attachment portions 41 and 45 may function as a guide when the cable is attached.

In this embodiment, each of the attachment portions 41 and 45 includes the portion 52 which protrudes toward the mask 25 farther than the display surface 5a. Therefore, the attachment portions 41 and 45 can function as supports interposed between the cover 26 and the mask 25. According to this structure, for example, when an external impact or stress is applied to the housing 4, the display device 5 is less likely to be interposed between the mask 25, and the cover 26 is less likely to be damaged. In this way, it is possible to protect the display device 5.

FIG. 10 illustrates a first modification of this embodiment. As illustrated in FIG. 10, in the first modification, the first projection 43 is a positioning pin (i.e., a positioning portion or a fixing portion) and does not include the inclined surface 43c. In this structure, first, the first projection 43 is inserted into the first opening 42. In this way, the first end 31 of the display device 5 is positioned.

After the first end 31 is positioned, the second opening 46 is guided by the inclined surface 47c of the second projection 47 and is fitted to the second projection 47. In this way, tensile stress is applied between the first end 31 and the second end 32. Instead of this modification, the second projection 47 may be a positioning pin and the first opening 42 may be guided by the inclined surface 43c of the first projection 43.

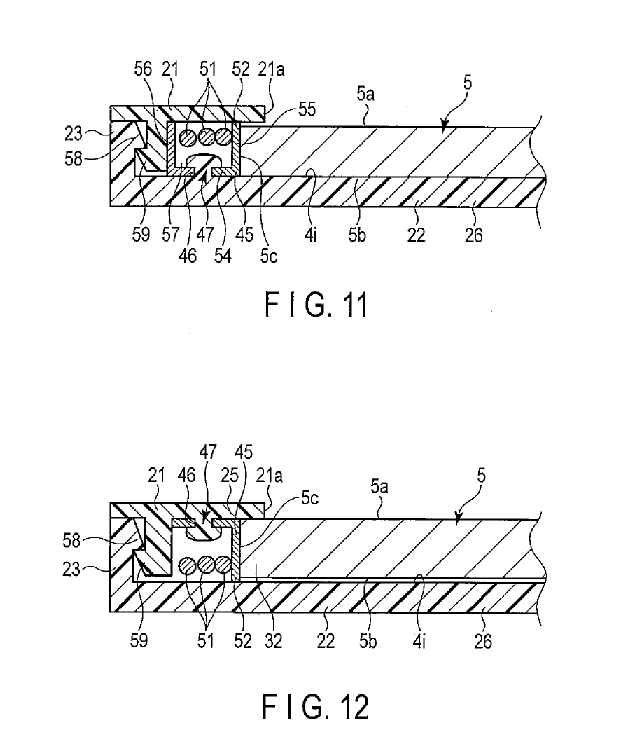

FIG. 11 illustrates a second modification of this embodiment. As illustrated in FIG. 11, each of the attachment portions 41 and 45 includes a first portion 54, a second portion 55, and a third portion 56. The first portion 54 is substantially parallel to the inner surface 41 of the housing 4. The first opening 42 or the second opening 46 is provided in the first portion 54 and the first portion 54 is welded to the first projection 43 or the second projection 47.

The second portion 55 rises from the end of the first portion 54 and is arranged along the side surface 5c (i.e., a circumferential surface or a third surface) of the display device 5. The second portion 55 is a fixing portion which is fixed to the display device 5. The third portion 56 is opposite to the second portion 55. The third portion 56 extends in a direction crossing (e.g., substantially perpendicular to) the inner surface 4i of the housing 4. The third portion 56 extends in the thickness direction of the housing 4.

In this way, in the attachment portions 41 and 45, a groove 57 (i.e., a concave portion or a guide) is provided between the second portion 55 and the third portion 56. The cable 51 is attached to the groove 57 and is accommodated in the groove 57.

As illustrated in FIG. 11, a receiving portion 58 (i.e., an engaged portion or a first engaging portion) is provided on the inner surface of the circumferential wall 23 of the cover 26. The mask 25 includes a claw portion 59 (i.e., an engaging portion or a second engaging portion) which protrudes toward the inside of the housing 4 and is engaged with the receiving portion 58 of the cover 26. When the claw portion 59 of the mask 25 is engaged with the receiving portion 58 of the cover 26, the mask 25 is fixed to the cover 26.

As illustrated in FIG. 11, a portion (e.g., third portion 56) of the attachment portion 41 or 45 is disposed between the cable 51 and the claw portion 59 of the mask 25. Therefore, when the mask 25 is combined with the cover 26, the cable 51 is less likely to be interposed between the claw portion 59 of the mask 25 and the receiving portion 58 of the cover 26. Therefore, it is not necessary to provide a separate member for preventing the interposition of the cable and it is possible to reduce the size and thickness of the electronic apparatus 11.

The receiving portion 58 may be provided in the attachment portion 41 or 45, instead of the cover 26. According to this structure, it is possible to reduce the manufacturing costs of the housing 4 and improve yield.

FIG. 12 illustrates a third modification of this embodiment. As illustrated in FIG. 12, the first projection 43 and the second projection 47 may be provided on the mask 25, instead of the cover 26. In this modification, the protruding portion 52 protrudes toward the cover 26 farther than the rear surface 5b of the display device 5.

The first to third modifications may be combined with each other. In addition, the first to third modifications may be independently applied to each of the following embodiments, or combinations of the first to third modifications may be applied to each of the following embodiments.

### Third Embodiment

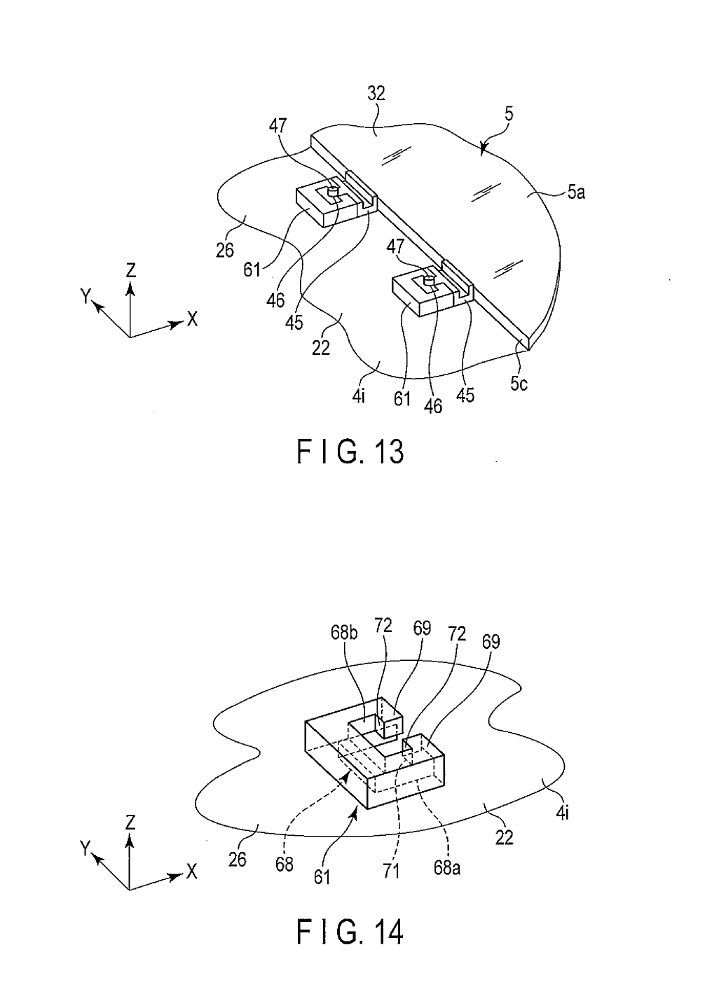

Next an electronic apparatus 11 according to a third embodiment will be described with reference to FIGS. 13 to 24. In the third embodiment, components having the same or similar functions as those in the second embodiment are denoted by the same reference numerals and the description thereof will not be repeated. In addition, structures other than the following structures are the same as those in the second embodiment.

In this embodiment, a housing 4 may be made of metal or plastic. In this embodiment, the electronic apparatus 11 includes a holder 61 (i.e., holding portion) and a supporting body 62 (i.e., supporter, or supporting portion), instead of the first projection 43 and the second projection 47 which are provided integrally with the housing 4. Next, the holder 61 and the supporting body 62 corresponding to the second projection 47 will be described in detail. The holder 61 and the supporting body 62 corresponding to the first projection 43 have the following structure.

As illustrated in FIGS. 13 and 14, the holder 61 is provided in the housing 4. The holder 61 may be provided integrally with the housing 4, or it may be provided separately from the housing 4 and fixed to the housing 4. The holder 61 may be made of metal or plastic.

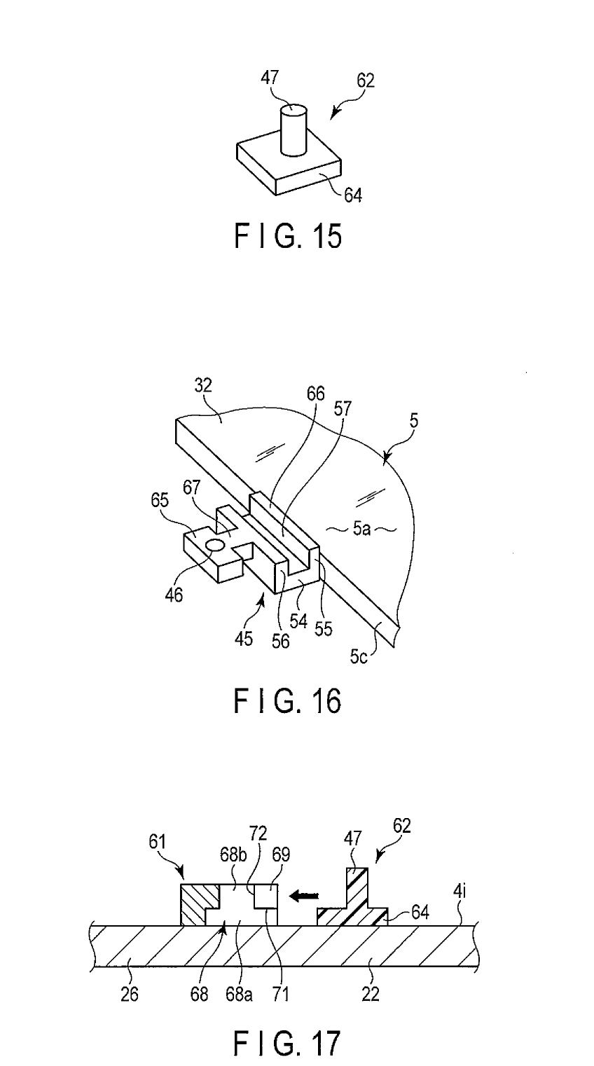

As illustrated in FIG. 15, the supporting body 62 includes a stand portion 64 (i.e., base portion) and a second projection 47 which is provided on the stand portion 64. The stand portion 64 has, for example, a flat rectangular parallelepiped shape. The second projection 47 rises from the substantially central portion of the stand portion 64. The supporting body 62 is made of plastic.

As illustrated in FIG. 16, an attachment portion 45 includes a first portion 65, a second portion 66, and a third portion 67. The first portion 65 has a flat rectangular parallelepiped shape and includes a second opening 46. The second portion 66 is attached to a display device 5. The third portion 67 is disposed between the first portion 65 and the second portion 66 and connects the first portion 65 and the second portion 66. The third portion 67 is thinner than the first portion 65.

For convenience of description, the first to third directions X, Y, and Z are defined. As illustrated in FIG. 14, the first direction X and the second direction Y are along the inner surface 4i of the housing 4. The first direction X is from the holder 61 to the display device 5. The second direction Y crosses (e.g., is substantially perpendicular to) the first direction X. The second direction Y is along the second end 32 of the display device 5. The third direction Z crosses (e.g., is substantially perpendicular to) the first direction X and the second direction Y. The third direction Z is substantially perpendicular to, for example, the inner surface 4i of the housing 4.

As illustrated in FIG. 14, the holder 61 includes a space portion 68 (i.e., a recessed portion, a receiving portion, or a engaging portion) and a pair of pressing portions 69 (i.e., supporting portions). The space portion 68 includes a first portion 68a and a second portion 68b. The first portion 68a has a shape (e.g., a shape which is substantially the same as the outer shape of the stand portion 64) corresponding to the stand portion 64 of the supporting body 62. The first portion 68a is opened in the first direction X.

The second portion 68b has a shape (a shape which is substantially the same as the outer shape of the first portion 65 and the third portion 67) corresponding to the first portion 65 and the third portion 67 of the attachment portion 45. The second portion 68b is opened in the first direction X and the third direction Z.

As illustrated in FIGS. 17 and 20, the supporting body 62 is attached to the holder 61 in the direction (e.g., direction opposite to the first direction X) from the display device 5 to the holder 61. The supporting body 62 is inserted into the space portion 68 of the holder 61. In this way, the supporting body 62 is removably supported by the holder 61. The pressing portion 69 includes a supporting surface 71 (i.e., first supporting surface) facing the stand portion 64 such that the supporting body 62 does not come off from the holder 61 in the direction (i.e., third direction Z) in which the second projection 47 protrudes.

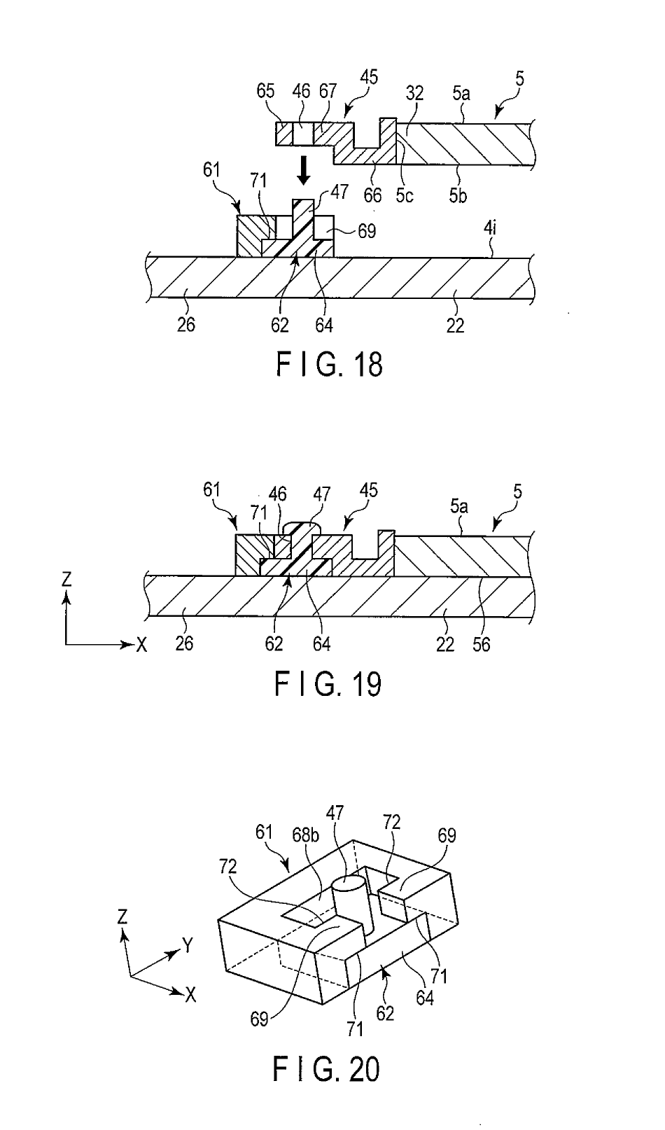

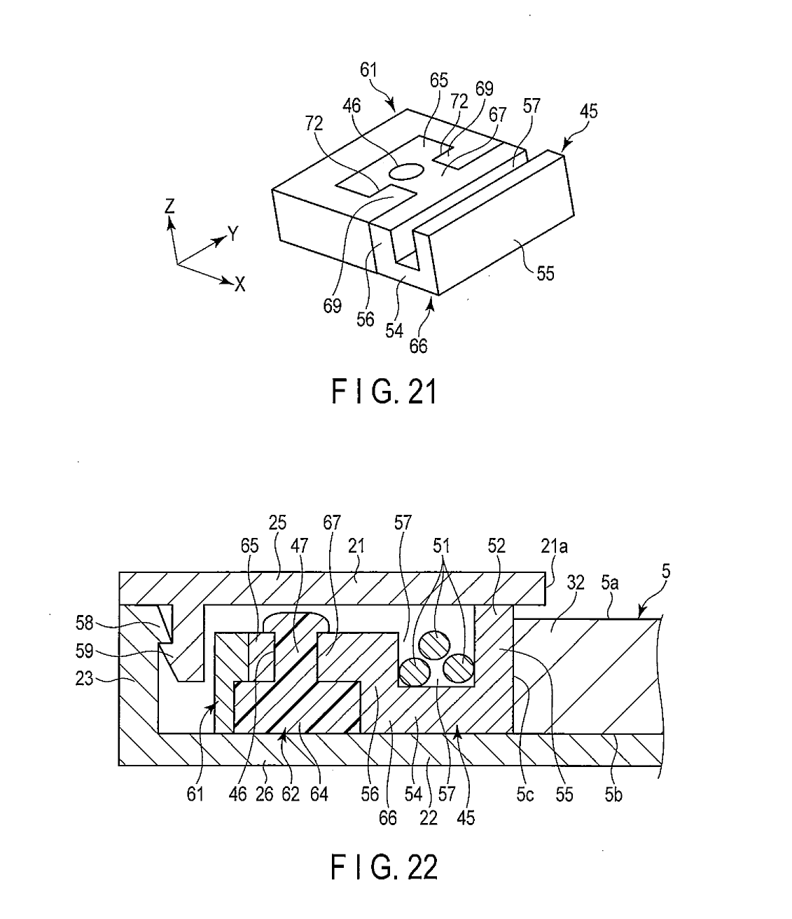

As illustrated in FIGS. 18 and 21, the first portion 65 of the attachment portion 45 is inserted into the second portion 68b of the space portion 68. The second opening 46 of the first portion 65 is engaged with the second projection 47 of the supporting body 62. The pressing portion 69 includes a supporting surface 72 (i.e., second supporting surface) facing the first portion 65 such that the supporting body 62 does not come off in the direction toward the first projection 43, in a state where the second projection 47 is inserted into the second opening 46.

Next, the operation of the holder 61 and the supporting body 62 will be described.

As illustrated in FIG. 17, first, the supporting body 62 is fitted to the holder 61 in the direction opposite to the first direction X. The supporting body 62 faces the supporting surface 71 of the holder 61 such that it does not come off in the third direction Z. Three surfaces of the stand portion 64 except for the surface in the first direction X come into contact with the inner surface of the holder 61. In this way, the rotation or the movement in the second direction Y of the supporting body 62 is regulated.

Then, as illustrated in FIG. 18, the first portion 65 of the attachment portion 45 is engaged with the supporting body 62. Specifically, the second projection 47 is inserted into the second opening 46. The attachment portion 45 faces the supporting surface 72 of the holder 61 such that it does not come off in the first direction X, in a state where the second projection 47 is inserted into the second opening 46. In this way, the supporting body 62 engaged with the attachment portion 45 does not come off in the first direction X.

Then, as illustrated in FIG. 19, the leading end of the second projection 47 is welded to the attachment portion 45 such that the attachment portion 45 does not come off from the second projection 47 in the third direction Z. In this way, the attachment portion 45 is fixed to the housing 4. The attachment portion 41 is fixed to the first projection 43 substantially in the same way as described above.

A distance L1 between the first projection 43 and the second projection 47 is greater than a distance L2 between the first opening 42 and the second opening 46. That is, the display device 5 is fixed to the housing 4 while being stretched by a predetermined distance. In this way, tensile stress is applied to the display device 5.

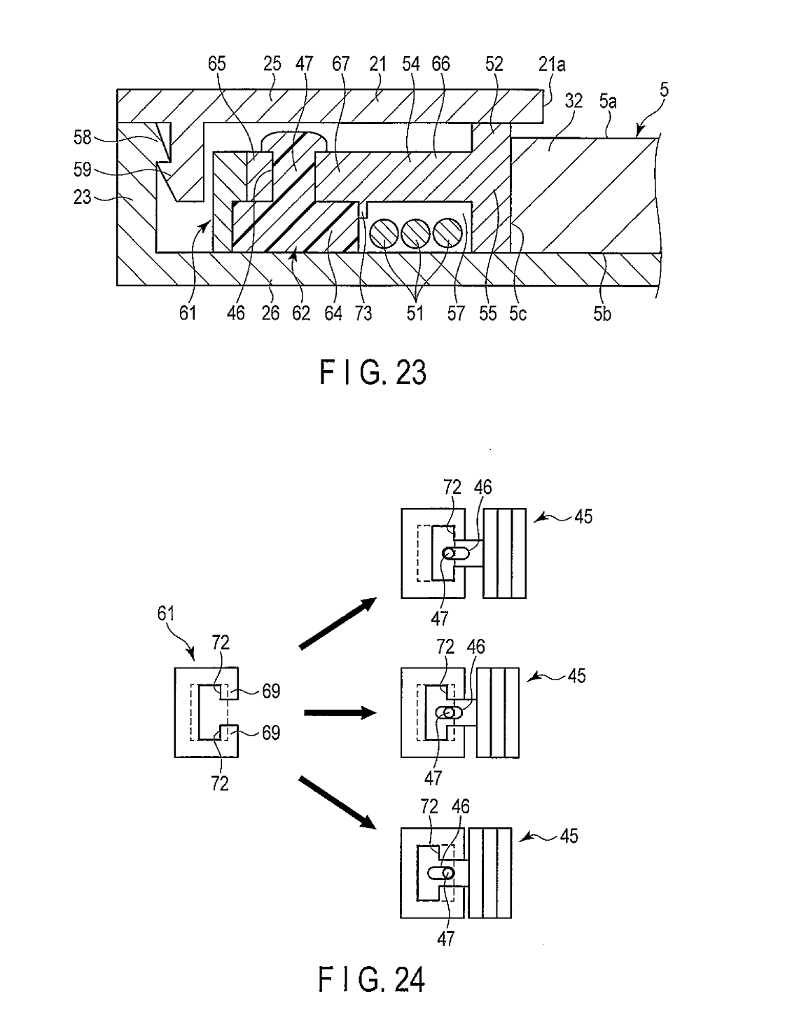

As illustrated in FIG. 22, a groove 57 is provided in the second portion 66. A plurality of cables 51 are accommodated in the groove 57. FIG. 23 illustrates a modification. As illustrated in FIG. 23, the groove 57 may face the cover 26. The attachment portion 45 includes a positioning convex portion 73 which comes into contact with the supporting body 62.

According to this structure, similarly to the second embodiment, it is possible to reduce the thickness of the electronic apparatus 11. This embodiment includes the holder 61 provided in the housing 4 and the supporting body 62 which is removably supported by the holder 61. Therefore, even when the housing 4 is made of a metal material, it can be fixed by plastic welding.

In this embodiment, the second projection 47 is provided in the supporting body 62. Therefore, for example, during maintenance, even when the welding portion is removed in order to detach the display device 5, a new supporting body 62 is prepared, which makes it possible to fix the display device 5 to the housing 4 again using welding. Therefore, it is possible to improve maintainability.

In this embodiment, the holder 61 includes the supporting surface 71 which faces the supporting body 62 such that the supporting body 62 does not come off from the holder 61 in the direction in which the second projection 47 protrudes. In this way, the position of the supporting body 62 is stabilized.

In this embodiment, the holder 61 includes the supporting surface 72 which faces the attachment portion 45, in the state where the second projection 47 is inserted into the second opening 46, such that the supporting body 62 does not come off from the holder 61 in the direction toward the first projection 43. In this way, even when the second projection 47 is softened during welding, it is possible to stabilize the position of the attachment portion 45.

As illustrated in FIG. 24, for example, post-processing may be performed on a portion which is represented by a dashed line in FIG. 24 to finely adjust tensile stress (i.e., pretension) applied to the display device 5. That is, the position of the supporting surface 72 is adjusted to adjust the position of the attachment portion 45. In this way, it is possible to change the amount of tension (i.e., the amount of stretching) of the display device 5 and thus adjust tensile stress. When the second opening 46 is a long hole, the second opening 46 is smoothly attached to the second projection 47.

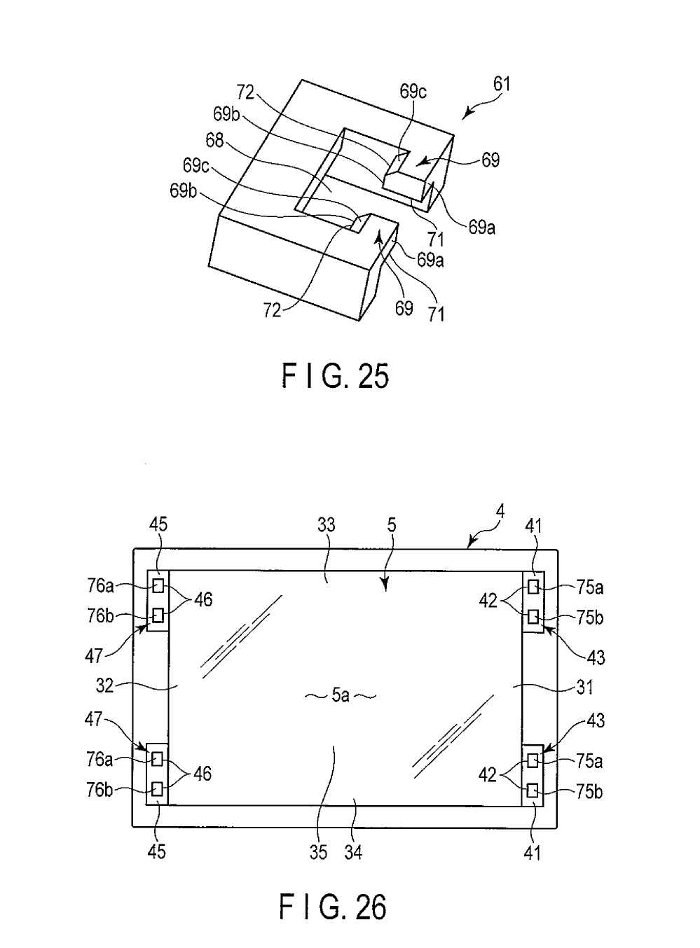

FIG. 25 illustrates a modification of this embodiment. As illustrated in FIG. 25, the pressing portion 69 includes a first side surface 69a facing the first projection 43 and a second side surface 69b opposite to the first side surface 69a. The second side surface 69b includes an inclined surface 69c which is inclined in the direction in which it is away from the first projection 43 while advancing from the upper surface of the pressing portion 69 toward the inner surface of the housing 4. According to this structure, the first portion 65 of the attachment portion 45 is guided by the inclined surface 69c and is then inserted into the space portion 68. In this way, the attachment portion 45 can be smoothly fitted to the holder 61.

### Fourth Embodiment

Next, an electronic apparatus 11 according to a fourth embodiment will be described with reference to FIG. 26. In the fourth embodiment, components having the same or similar functions as those in the second and third embodiments are denoted by the same reference numerals and the description thereof will not be repeated. In addition, structures other than the following structures are the same as those in the second embodiment.

As illustrated in FIG. 26, each first attachment portion 41 includes a plurality of first openings 42. A plurality of first projections 43 are engaged with the plurality of first openings 42. Each of the plurality of first projections 43 includes a first pin 75a and a second pin 75b. The first pin 75a and the second pin 75b are independent from each other.

Similarly, each second attachment portion 45 includes a plurality of second openings 46. A plurality of second projections 47 are engaged with the plurality of second openings 46. Each of the plurality of second projections 47 includes a first pin 76a and a second pin 76b. The first pin 76a and the second pin 76b are independent from each other.

In a welding process, first, the first pin 75a of the first projection 43 and the first pin 76a of the second projection 47 are welded. At that time, the display device 5 is supported while tensile stress is applied thereto by the second pin 75b of the first projection 43 and the second pin 76b of the second projection 47.

Then, the second pin 75b of the first projection 43 and the second pin 76b of the second projection 47 are welded. At that time, the display device 5 is supported while tensile stress is applied thereto by the welded first pin 75a of the first projection 43 and the welded first pin 76a of the second projection 47.

According to this structure, similarly to the second embodiment, it is possible to reduce the thickness of the electronic apparatus 11. In this embodiment, each of the plurality of first projections 43 includes the first pin 75a and the second pin 75b which are independently welded. Each of the plurality of second projections 47 includes the first pin 76a and the second pin 76b which are independently welded. According to this structure, it is possible to stably support the display device 5.

### Fifth Embodiment

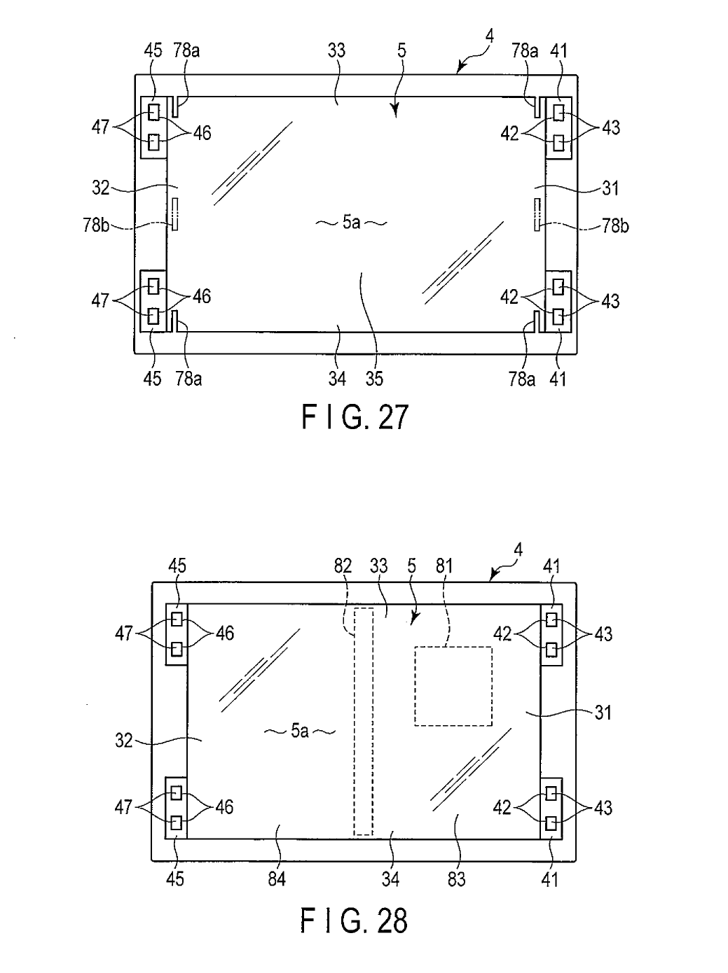

Next, an electronic apparatus 11 according to a fifth embodiment will be described with reference to FIG. 27. In the fifth embodiment, components having the same or similar functions as those in the second to fourth embodiments are denoted by the same reference numerals and the description thereof will not be repeated. In addition, structures other than the following structures are the same as those in the second embodiment.

As illustrated in FIG. 27, a display device 5 according to this embodiment includes cutouts 78a. The cutout 78a extends between a first opening 42 and a second opening 46. In this way, the display device 5 is more likely to be stretched between a first end 31 and a second end 32. In addition, the display device 5 includes slits 78b, instead of the cutouts 78a or in addition to the cutouts 78a. The slit 78b extends between the first opening 42 and the second opening 46.

According to this structure, similarly to the second embodiment, it is possible to reduce the thickness of the electronic apparatus 11. In this embodiment, since the cutout 78a is provided in the display device 5, it is easy for the display device 5 to be stretched. According to this structure, it is easy to adjust tensile stress (pretension).

### Sixth Embodiment

Next, an electronic apparatus 11 according to a sixth embodiment will be described with reference to FIG. 28. In the sixth embodiment, components having the same or similar functions as those in the second to fifth embodiments are denoted by the same reference numerals and the description thereof will not be repeated. In addition, structures other than the following structures are the same as those in the second embodiment.

As illustrated in FIG. 28, in this embodiment, a heat generating component 81 is provided on the rear side of a display device 5. A portion of the display device 5 is affected by heat generated from the heat generating component 81 and is thermally expanded. Therefore, in this embodiment, a fixing portion 82 for fixing the display device 5 and a housing 4 is provided. An example of the fixing portion 82 is a double-sided tape which adheres the display device 5 and the housing 4.

In this way, the display device 5 includes a first region 83 which is disposed between the fixing portion 82 and a first end 31 and a second region 84 which is disposed between the fixing portion 82 and a second end 32. The first region 83 is affected by heat generated from the heat generating component 81. The second region 84 is less affected by heat generated from the heat generating component 81 than the first region 83. In this embodiment, the positions of openings 42 and 46 and projections 43 and 47 are adjusted such that the tensile stress of the first region 83 is greater than that of the second region 84.

According to this structure, similarly to the second embodiment, it is possible to reduce the thickness of the electronic apparatus 11. In this embodiment, the magnitude of tensile stress is partially adjusted according to the influence of heat. According to this structure, it is possible to apply appropriate tensile stress to the display device 5 and improve the parallelism of a display surface 5a.

### Seventh Embodiment

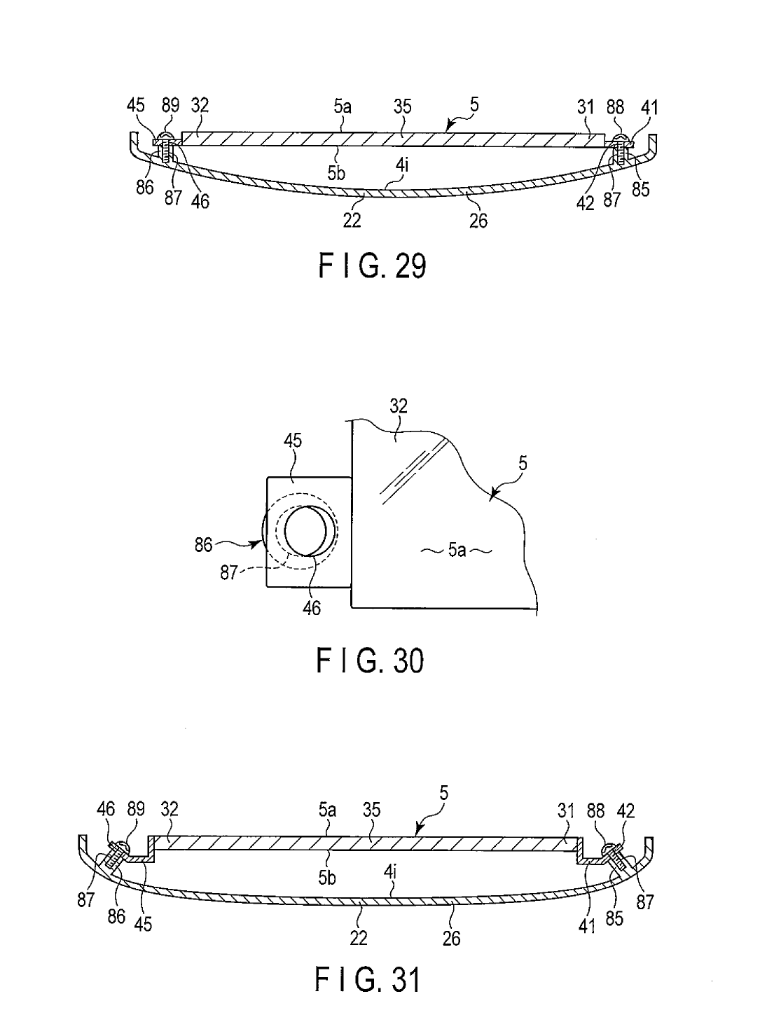

Next, an electronic apparatus 11 according to a seventh embodiment will be described with reference to FIGS. 29 and 30. In the seventh embodiment, components having the same or similar functions as those in the second to sixth embodiments are denoted by the same reference numerals and the description thereof will not be repeated. In addition, structures other than the following structures are the same as those in the second embodiment.

As illustrated in FIG. 29, in this embodiment, a portion of a cover 26 has an arc shape. A central portion of a display device 5 is separated from the cover 26 with a space therebetween. The cover 26 includes a first boss 85 (i.e., first supporting portion) and a second boss 86 (i.e., second supporting portion). Screw holes 87 are provided in the first boss 85 and the second boss 86.

A first end 31 of the display device 5 faces the first boss 85. A first opening 42 corresponding to the screw hole 87 of the first boss 85 is provided at the first end 31. The first screw 88 passes through the first opening 42 and is inserted into the screw hole 87. In this way, the first end 31 is fixed to the first boss 85.

A second end 32 of the display device 5 faces the second boss 86. A second opening 46 corresponding to the screw hole 87 of the second boss 86 is provided at the second end 32. The second screw 89 passes through the second opening 46 and is inserted into the screw hole 87. In this way, the second end 32 is fixed to the second boss 86.

The screw hole 87 of the second boss 86 deviates from the second opening 46 of the display device 5 in a direction opposite to the first boss 85. That is, a distance L1 between the first boss 85 and the second boss 86 is greater than a distance L2 between the first opening 42 and the second opening 46. In this way, when the display device 5 is fixed to the housing 4, tensile stress is applied to the display device 5.

According to this structure, similarly to the second embodiment, it is possible to reduce the thickness of the electronic apparatus 11. In this embodiment, tensile stress is applied to the display device 5 by the bosses 85 and 86 and it is possible to improve the parallelism of a display surface 5a.

### Eighth Embodiment

Next, an electronic apparatus 11 according to an eighth embodiment will be described with reference to FIG. 31. In the eighth embodiment, components having the same or similar functions as those in the second to seventh embodiments are denoted by the same reference numerals and the description thereof will not be repeated. In addition, structures other than the following structures are the same as those in the second embodiment.

A cover 26 includes a first boss 85 (i.e., first supporting portion) and a second boss 86 (i.e., second supporting portion). Each of the first boss 85 and the second boss 86 is inclined in the direction in which the bosses 85, 86 are away from the display device 5 while advancing from the leading end toward the base end of each of the bosses 85, 86.

According to this structure, similarly to the second embodiment, it is possible to reduce the thickness of the electronic apparatus 11. In this embodiment, in the process of tightening a first screw 88 and a second screw 89, tensile stress is applied to the display device 5 and it is possible to improve the parallelism of a display surface 5a.

### Ninth Embodiment

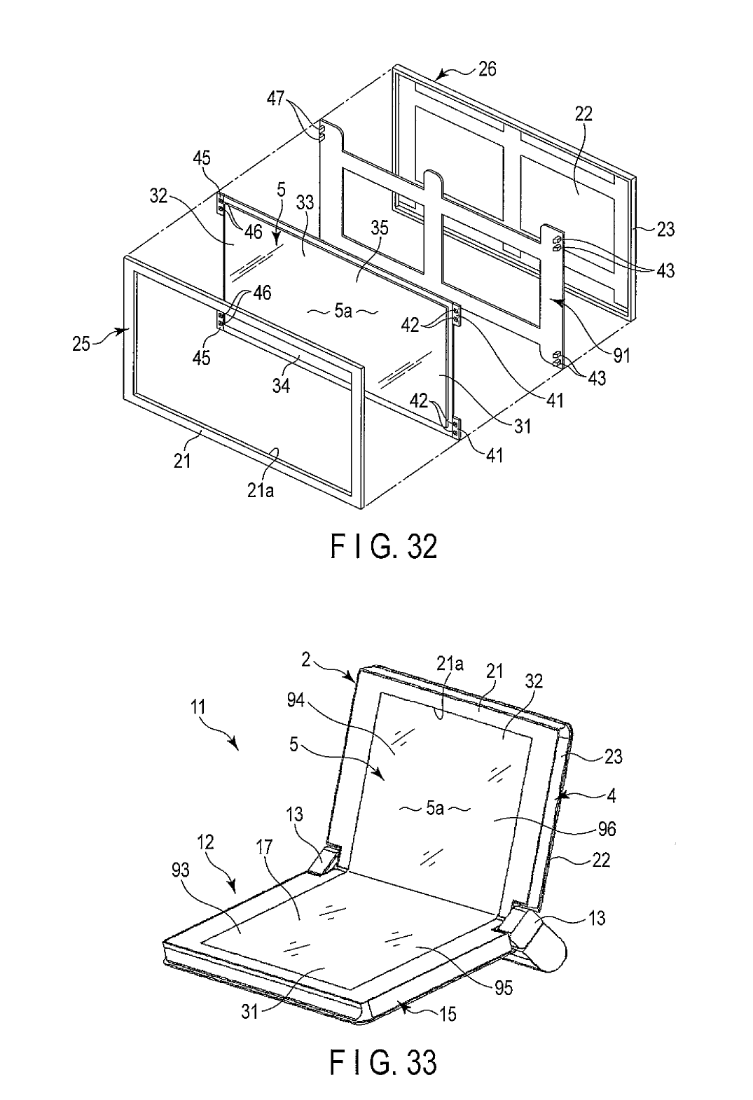

Next, an electronic apparatus 11 according to a ninth embodiment will be described with reference to FIG. 32. In the ninth embodiment, components having the same or similar functions as those in the second to eighth embodiments are denoted by the same reference numerals and the description thereof will not be repeated. In addition, structures other than the following structures are the same as those in the second embodiment.

As illustrated in FIG. 32, in this embodiment, a back plate 91 (i.e., a reinforcing member, a reinforcing portion, a metal portion, a supporting portion, or a holder) is provided between a display device 5 and a cover 26. The back plate 91 includes a first projection 43 and a second projection 47.

According to this structure, similarly to the second embodiment, it is possible to reduce the thickness of the electronic apparatus 11. In this embodiment, tensile stress is applied to the display device 5 by the back plate 91 and it is possible to improve the parallelism of a display surface 5a.

### Tenth Embodiment

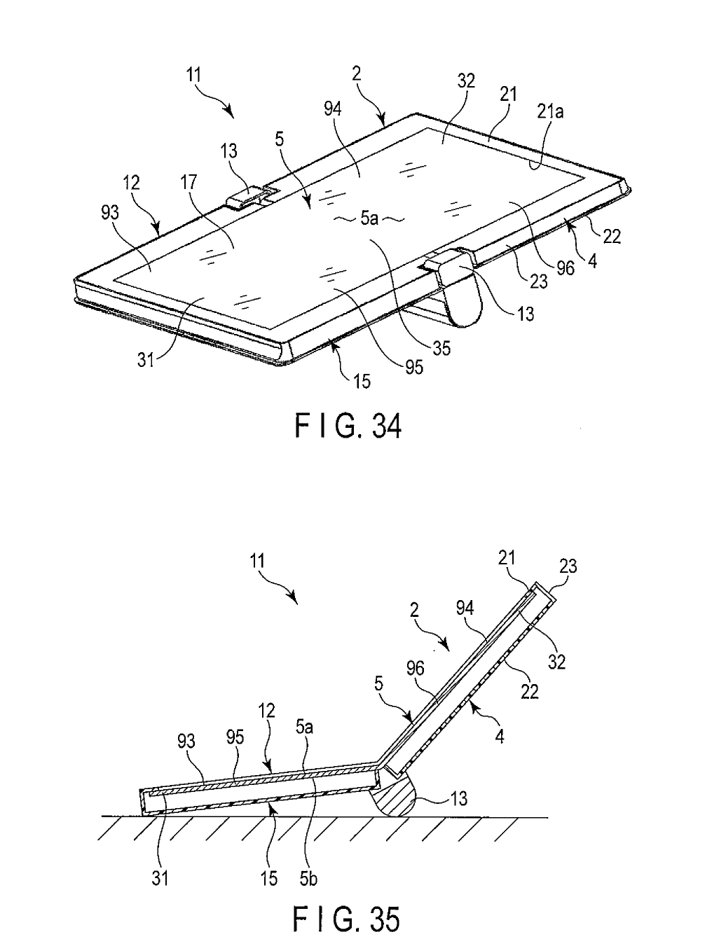

Next, an electronic apparatus 11 according to a tenth embodiment will be described with reference to FIGS. 33 to 35. In the tenth embodiment, components having the same or similar functions as those in the second to ninth embodiments are denoted by the same reference numerals and the description thereof will not be repeated. In addition, structures other than the following structures are the same as those in the second embodiment.

As illustrated in FIGS. 33 to 35, a first unit 12 includes a first display portion 93. A second unit 2 includes a second display portion 94. In this embodiment, one display device 5 is provided over the first unit 12 and the second unit 2.

That is, the display device 5 includes a first portion 95 in the first unit 12 and a second portion 96 in the second unit 2. The first portion 95 forms the first display portion 93 and includes a first end 31. The second portion 96 forms the second display portion 94 and includes a second end 32.

The display device 5 can be deformed between a first state where the first portion 95 and the second portion 96 are rotated about a hinge portion 13 to overlap each other and a second state where the first portion 95 and the second portion 96 are rotated about the hinge portion 13 to be opened. A display surface 5a is flattened at the second state rather than at the first state. That is, tensile stress is applied between the first end 31 and the second end 32 of the display surface 5a at the second position.

According to this structure, similarly to the second embodiment, it is possible to reduce the thickness of the electronic apparatus 11. In this embodiment, tensile stress is applied between the first end 31 and the second end 32 of the display surface 5a at the second position. In this way, it is possible to improve the parallelism of the display surface 5a when the electronic apparatus is used with the first unit 12 and the second unit 2 opened.

The embodiments are not limited to the above-described embodiments, but the components according to the above-described embodiments may be changed without departing from the scope and spirit of the invention. In addition, a plurality of components according to the above-described embodiments may be appropriately combined with each other to form various structures. For example, some of the components according to the above-described embodiments may be removed. Components according to different embodiments may be appropriately combined with each other.

For example, the first and second openings 42 and 46 may be provided in a metal plate attached to the display device 5, or they may be directly provided in the display device 5.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a housing comprising a cover;
a flexible display in the housing, the display comprising
a first end comprising a first opening,
a second end, opposite the first end,
comprising a second opening,
a display surface between the first end and the second end, and
a rear surface opposite the display surface and facing the cover;
a first projection on an inner surface of the housing, the first projection configured to engage with the first opening; and
a second projection on the inner surface of the housing, the second projection configured to engage with the second opening,
wherein a first distance between the first projection and the second projection is greater than a second distance between the first opening and the second opening, and
a portion of the rear surface between the first opening and the second opening is configured to be movable with respect to the cover.

2. The television of claim 1,
wherein the second projection comprises a first side facing the first projection and a second side opposite the first side, and
the second side comprises a surface inclined in a direction away from the first projection and advancing from an end of the second projection toward the inner surface of the housing.

3. The television of claim 2,
wherein the second opening is configured to be guided by the inclined surface and to engage with the second projection such that tensile stress is applied between the first end and the second end of the display.

4. The television of claim 1,
wherein the second opening has a rectangular shape,
the second projection has a rectangular cross section corresponding to the second opening, and
a rotation of the display is regulated when the second projection is engaged with the second opening.

5. The television of claim 1,
wherein the display comprises a metal attachment, the attachment comprising the second opening, and
the second projection is configured to be welded or otherwise attached to the attachment in a state where the second projection is engaged with the second opening.

6. The television of claim 5, further comprising:
a cable in the housing,
wherein the housing comprises a first wall comprising an opening exposing the display surface,
the cover comprises a second wall opposite the first wall and comprising the first projection and the second projection, and
a portion of the cable is between the second projection and the first wall.

7. The television of claim 6,
wherein a portion of the attachment protrudes toward the first wall farther than the display surface.

8. The television of claim 5, further comprising:
a holder in the housing; and
a supporter configured to be removably supported by the holder and comprising the second projection,
wherein the holder comprises a first surface configured to face the supporter such that the supporter does not detach from the holder in a direction in which the second projection protrudes.

9. The television of claim 8,
wherein the holder comprises a second surface configured to face the attachment such that the supporter does not detach from the holder toward the first projection in a state where the second projection is engaged with the second opening.

10. An electronic apparatus comprising:
a housing;
a flexible display in the housing, the display comprising
a first end comprising a first engaging portion, and
a second end opposite the first end and comprising a second engaging portion;
a first supporter in the housing, the first supporter configured to receive the first engaging portion; and
a second supporter in the housing, the second supporter configured to receive the second engaging portion,
wherein a portion of the display between the first engaging portion and the second engaging portion is configured to be movable with respect to the housing.

11. An electronic apparatus comprising:
a housing; and
a flexible display in the housing,
wherein a central portion of the display is free from the housing, and at least two ends of the display are attached to the housing.
